(19) United States
(12) Patent Application Publication
(10) Pub. No.: US 2020/0192528 A1
(43) Pub. Date: Jun. 18, 2020

(54) DETECTING SYSTEM AND DETECTING METHOD

(71) Applicant: Coretronic Corporation, Hsin-Chu (TW)

(72) Inventor: CHIA-CHENG WU, Hsin-Chu (TW)

(21) Appl. No.: 16/716,530

(22) Filed: Dec. 17, 2019

(30) Foreign Application Priority Data
Dec. 18, 2018 (CN) 201811548588.9

(51) Int. Cl. G06F 3/044; H03K 17/96

(52) U.S. Cl. CPC G06F 3/0447; H03K 17/962; G06F 3/0445

(57) ABSTRACT

Detecting system and detecting method are for detecting deformation degree of capacitive touch device's touch surface. Detecting system has a deformation detecting component and a computer. The deformation detecting component has two conductive supporters, conductive reference member mounted on the conductive supporters and having straight edge, and deformation degree measuring member. The conductive base has a measuring surface, a bottom surface, and an acute angle formed between the bottom surface and the measuring surface. The electrical conductor layers are sequentially arranged on the measuring surface and have different electrical impedance values. When the deformation degree measuring member is inserted between the straight edge, the conductive supporters and the touch surface, the conductive base, the conductor layers and the straight edge are electrically conducted, the capacitive touch device generates deformation degree signal. The computer receives the deformation degree signal and generates a deformation degree data.

### CROSS-REFERENCE TO RELATED APPLICATION

This application claims the priority benefit of CN201811548588.9, filed on Dec. 18, 2018. The entirety of the above-mentioned patent application is hereby incorporated by reference herein and made a part of this specification.

### FIELD OF THE INVENTION

The invention relates to a detecting system and detecting method.

### BACKGROUND OF THE INVENTION

Due to the influence of materials, assembly, and environment, the touch surface of the capacitive touch whiteboard is often deformed (recessed, protruded) during manufacturing process. While a writer uses a touch-capacitor pen on a capacitive touch whiteboard that has a large degree of deformation, the writer's physical and electronic handwriting, text and graphic records can be biased in the visual observation of users and participants. The accuracy of the digital record coordinate points stored in real time is also biased. In addition, while the writer uses a touch-capacitor board eraser on the capacitive touch whiteboard, the writer needs to wipe off the physical handwriting and the electronic handwriting, text, and graphic record at the same time. Deviations also exist in the visual observations of the users and the participants, and the accuracy of the digital record coordinate points stored in real time can be also biased at the same time, and limit subsequent broader application and resource sharing.

Generally, users or manufacturers cannot distinguish whether the capacitive touch whiteboard is flat or whether the deformation degree of the capacitive touch whiteboard is within an allowable range by visually inspecting or touching the appearance shape. Hence, an external precision measuring device (including a digital vernier caliper, a digital scale, etc.) is equipped to detect the deformation degree of the touch surface of the capacitive touch whiteboard. However, a considerable amount of labor, equipment, space, and training costs are required for detecting the degree of deformation of the touch surface of the capacitive touch whiteboard. In addition, the measuring device has poor portability, and thereby resulting in inconvenience in use.

Therefore, the cost for detecting the deformation degree of the capacitive touch whiteboard is quite expensive and the portability of the device used is not good.

The information disclosed in this “BACKGROUND OF THE INVENTION” section is only for enhancement understanding of the background of the invention and therefore it may contain information that does not form the prior art that is already known to a person of ordinary skill in the art. Furthermore, the information disclosed in this “BACKGROUND OF THE INVENTION” section does not mean that one or more problems to be solved by one or more embodiments of the invention were acknowledged by a person of ordinary skill in the art.

### SUMMARY OF THE INVENTION

The invention provides a detecting system, which can reduce the cost of detecting deformation degree and has good portability.

The invention also provides a detecting method, which can reduce the cost of detecting deformation degree and the detecting tools used therein have good portability.

Other advantages and objects of the invention may be further illustrated by the technical features broadly embodied and described as follows.

In order to achieve one or a portion of or all of the objects or other objects, an embodiment of the invention provides a detecting system configured to detect the deformation degree of a touch surface of a capacitive touch device. The detecting system includes at least one deformation detecting component and a computer. Each of the at least one deformation detecting component includes two conductive supporters, an electrically conductive reference number, and at least one deformation degree measuring member. The two conductive supporters are opposite to each other. Two opposite ends of the conductive reference member are mounted on the conductive supporters respectively. The conductive reference member has a straight edge. A space is formed between the straight edge, the conductive supporters, and the touch surface. Each of the at least one deformation degree measuring member includes a conductive base and a plurality of electrical conductor layers. The conductive base has a measuring surface and a bottom surface. The measuring surface has a first edge and a second edge opposite the first edge. The bottom surface is connected with the first edge. An acute angle is formed between the bottom surface and the measuring surface. The electrical conductor layers are sequentially arranged on the measuring surface from the first edge toward the second edge, and the electrical conductor layers have different electrical impedance values. When the at least one deformation degree measuring member is inserted in the space, the bottom surface contacts a position of the touch surface, and at least one of the electrical conductor layers of the at least one deformation degree measuring member contacts the straight edge, the capacitive touch device correspondingly generates a deformation degree signal. The computer receives the deformation degree signal and further generates a deformation degree data corresponding to the position of the touch surface according to the deformation degree signal.

In order to achieve one or a portion of or all of the objects or other objects, an embodiment of the invention provides a detecting method for detecting the deformation degree of a touch surface of a capacitive touch device. The capacitive touch device includes the touch surface and a frame. The frame is connected with a peripheral edge of the touch surface. The detecting method includes: providing the at least one deformation degree measuring member mentioned above; mounting two opposite ends of a conductive reference member on two conductive supporters and disposing the two conductive supporters on the frame, so as to locate the conductive reference member above the touch surface and form a space between a straight edge of the conductive reference member, the two conductive supporters, and the touch surface; inserting each of the at least one deformation degree measuring member into the space to bring the bottom surface of the conductive base of each of the at least one deformation degree measuring member into contact with a position of the touch surface and bring at least one of the electrical conductor layers of each of the at least one deformation degree measuring member into contact with the straight edge, so as to electrically conduct the conductive reference member and the two conductive supporters and cause the capacitive touch device to generate a deformation degree signal; and receiving the deformation degree signal and further generating a deformation degree data corresponding to the position of the touch surface according to the deformation degree signal by a computer electrically connected with the touch surface.

When applying the detecting system and the detecting method of the invention to detect the deformation degree of the touch surface of the capacitive touch device, the inspector only needs to mount the conductive reference member having the straight edge on the conductive supporters to form the space between the straight edge, the conductive supporters, and the touch surface, and then inserting the deformation degree measuring member in the space to bring the bottom surface of the conductive base of the deformation degree measuring member into contact with a position of the touch surface and bring at least one of the electrical conductor layers sequentially arranged on the measuring surface of the conductive base from the first edge toward the second edge into contact with the straight edge, so as to cause the capacitive touch device to generate the deformation degree signal. Lastly, the computer is utilized to generate the deformation degree data corresponding to the position of the touch surface according to the deformation degree signal, and the inspector can know the deformation degree of the touch surface of the capacitive touch device. Accordingly, the detecting system and the detecting method of the invention can reduce the time cost for detecting the deformation degree. In addition, the detecting system of the invention and the detecting tool (the conductive reference member, the conductive supporters, the deformation degree measuring member, and the computer) used in the detecting method of the invention have a simple structure, and are easy to disassemble and assemble, and thereby being convenient for carrying.

Other objectives, features and advantages of the invention can be further understood from the further technological features disclosed by the embodiments of The invention wherein there are shown and described preferred embodiments of this invention, simply by way of illustration of modes best suited to carry out the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a use schematic diagram of a detecting system in accordance with an embodiment of the invention;

FIG. 2 is a schematic top view of a capacitive touch device and a deformation detecting component shown in FIG. 1;

FIG. 3 is a schematic side view of the capacitive touch device and the deformation detecting component shown in FIG. 1;

FIG. 4 is a schematic appearance of a deformation degree measuring member shown in FIG. 1;

FIG. 5 is a schematic side view of FIG. 4;

FIG. 6 is a schematic exploded view of the deformation degree measuring member shown in FIG. 1;

FIG. 7 is a schematic component view of conductive supporters and a conductive reference member shown in FIG. 1;

FIG. 8 is a schematic exploded view of the conductive supporters and the conductive reference member shown in FIG. 7;

FIG. 9 is a use schematic diagram of a detecting system in accordance with an embodiment of the invention; and

FIG. 10 is a flow diagram of a detecting method in accordance with an embodiment of the invention.

### DETAILED DESCRIPTION OF PREFERRED EMBODIMENTS

In the following detailed description of the preferred embodiments, reference is made to the accompanying drawings which form a part hereof, and in which is shown by way of illustration specific embodiments in which the invention may be practiced. In this regard, directional terminology, such as “top”, “bottom”, “front”, “back”, etc., is used with reference to the orientation of the Figure(s) being described. The components of the invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the invention. Also, it is to be understood that the phraseology and terminology used herein are for the purpose of description and should not be regarded as limiting. The use of “including”, “comprising”, or “having” and variations thereof herein is meant to encompass the items listed thereafter and equivalents thereof as well as additional items. Unless limited otherwise, the terms “connected”, “coupled”, and “mounted” and variations thereof herein are used broadly and encompass direct and indirect connections, couplings, and mountings. Similarly, the terms “facing”, “faces”, and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component facing “B” component directly or one or more additional components is between “A” component and “B” component. Also, the description of “A” component “adjacent to” “B” component herein may contain the situations that “A” component is directly “adjacent to” “B” component or one or more additional components is between “A” component and “B” component. Accordingly, the drawings and descriptions can be regarded as illustrative in nature and not as restrictive.

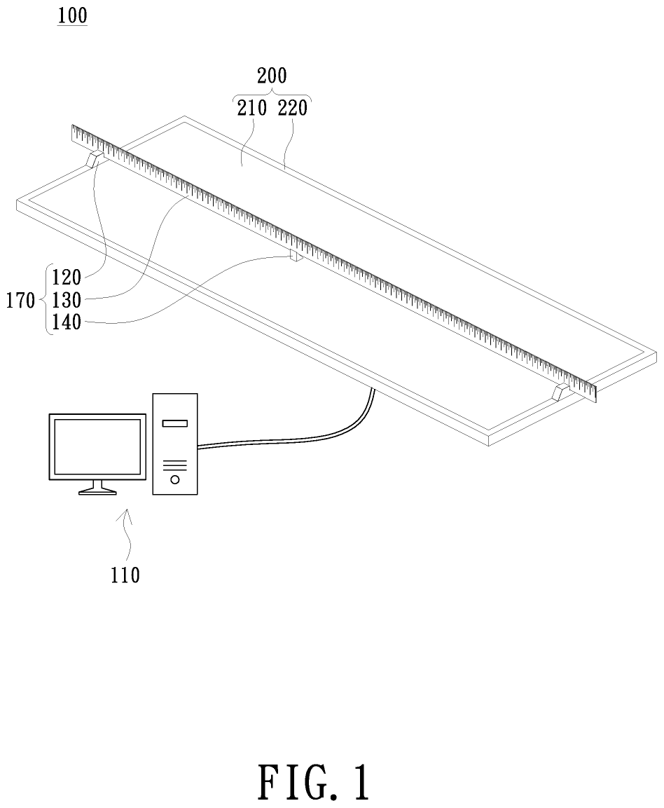

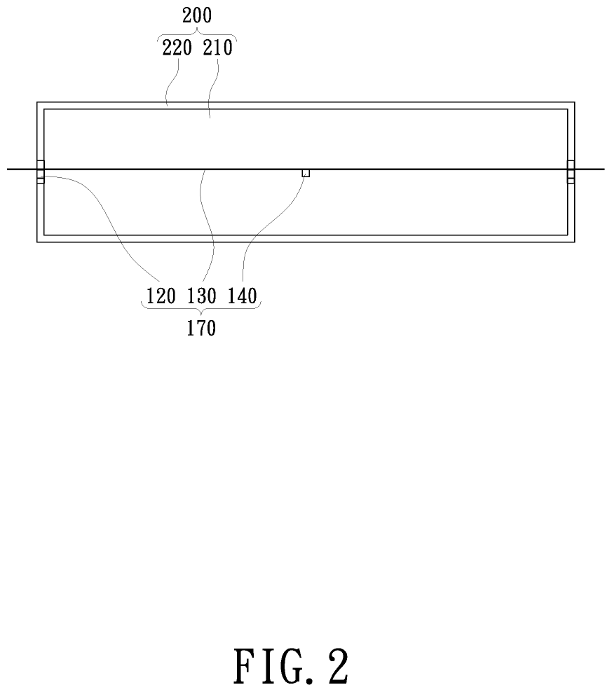

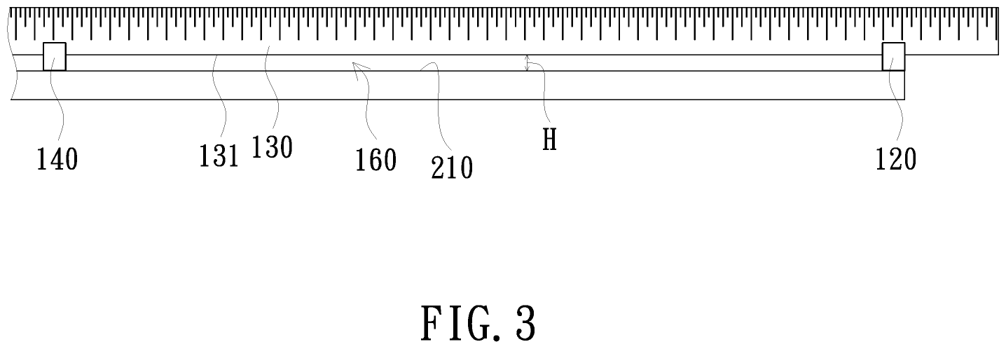

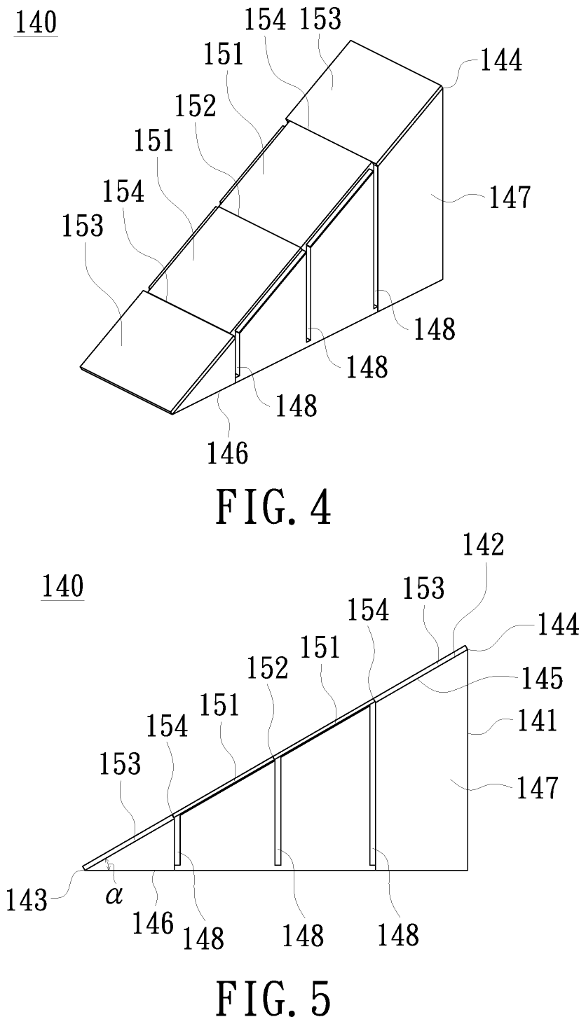

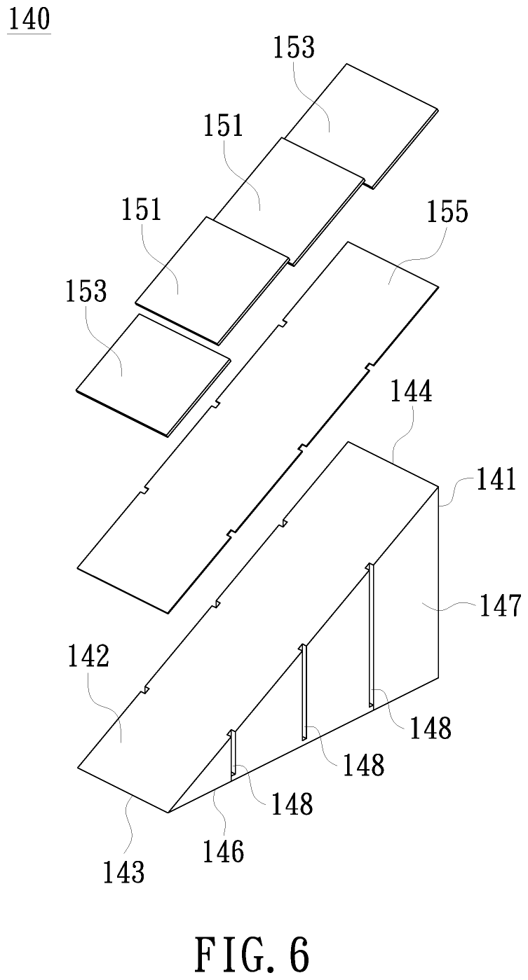

FIG. 1 is a use schematic diagram of a detecting system in accordance with an embodiment of the invention. FIG. 2 is a schematic top view of a capacitive touch device and a deformation detecting component shown in FIG. 1. FIG. 3 is a schematic side view of the capacitive touch device and the deformation detecting component shown in FIG. 1. FIG. 4 is a schematic appearance of a deformation degree measuring member shown in FIG. 1. FIG. 5 is a schematic side view of FIG. 4. FIG. 6 is a schematic exploded view of the deformation degree measuring member shown in FIG. 1. Referring to FIGS. 1 to 6, a detecting system 100 of the embodiment is configured to detect a deformation degree of a touch surface 210 of a capacitive touch device 200. The detecting system 100 includes a deformation detecting component 170 and a computer 110. The deformation detecting component 170 includes two conductive supporters 120 opposite to each other, a conductive reference member 130, and a deformation degree measuring member 140. All of outer surfaces of the conductive reference member 130 and the conductive supporters 120 are electrically conductive. Two opposite ends of the conductive reference member 130 are mounted on the two conductive supporters 120 respectively. The conductive reference member 130 has a straight edge 131. A space 160 is formed between the straight edge 131 of the conductive reference member 130, the conductive supporters 120, and the touch surface 210. The deformation degree measuring member 140 includes a conductive base 141 and a plurality of electrical conductor layers 151. The conductive base 141 has a measuring surface 142 and a bottom surface 146. The measuring surface 142 has a first edge 143 and a second edge 144 opposite the first edge 143. The bottom surface 146 is connected to the first edge 143, and an acute angle a is formed between the bottom surface 146 and the measuring surface 142. The electrical conductor layers 151 are sequentially arranged on the measuring surface 142 from the first edge 143 toward the second edge 144, and the electrical conductor layers 151 have different electrical impedance values. In addition, in the embodiment, the conductive reference member 130 may be a straight ruler, the conductive base 141 may be a wedge block, and the computer 110 may be, for example, an electronic device having computing function, such as a desktop computer, a notebook computer, and a tablet computer, but the invention is not limited thereto. Further, the capacitive touch device 200 may be, for example, electronic touch whiteboard or blackboard, but the invention is not limited thereto.

The detecting system 100 of the embodiment is applicable to detect the deformation degree of the touch surface 210 of the capacitive touch device 200. The capacitive touch device 200 may include a frame 220. The frame 220 is connected to a peripheral edge of the touch surface 220. While detecting, the computer 110 and the touch surface 210 of the capacitive touch device 200 are electrically connected, the computer 110 can receive a signal generated by the capacitive touch device 200, and the two conductive supporters 120 are oppositely disposed on the frame 220 to locate the conductive reference member 130 above the touch surface 210. The space 160 is inserted in the deformation degree measuring member 140 (formed between the straight edge 131, the conductive supporters 120, and the touch surface 210) and the bottom surface 146 of the conductive base 146 contacts a position of the touch surface 210, and at least one of the plurality of electrical conductor layers 151 of the deformation degree measuring member 140 contacts the straight edge 131. As mentioned above, the capacitive touch device 200 can sense a deformation degree signal generated by the deformation degree measuring member 140 and output the deformation degree signal to the computer 110. The computer 110 can receive the deformation degree signal and generate a deformation degree data corresponding to the position of the touch surface 210 according to the deformation degree signal. The inspector can know the deformation degree of the touch surface 210 of the capacitive touch device 200 according to the deformation degree data. In addition, when the conductive reference member 130 is placed over the touch surface 210, the conductive reference member 130 may be grounded before the detection is started.

In particular, the electrical conductor layers 151 have different impedance values; hence, after at least one of the plurality of electrical conductor layers 151 contacts the straight edge 131, the deformation degree signal generated by the capacitive touch device 200 can be corresponded to at least one specific electrical conductor layer 151 by the analytical comparison of the computer 110. In addition, the electrical conductor layers 151 are disposed on the measuring surface 142, and the acute angle a is formed between the measuring surface 142 and the bottom surface 146; that is, the distance between an electrical conductor layer 151 and the bottom surface 146 is specific. Accordingly, the computer 110 may derive the distance between the straight edge 131 and the position of the touch surface 210 after the deformation degree signal corresponds at least one specific electrical conductor layer 151, (since the straight edge 131 of the conductive reference member 130 contacts the specific at least one electrical conductor layer 151 and the bottom surface 146 of the conductive base 141 contacts the position of the touch surface 210), and the deformation degree of the position of the touch surface 210, for example, recessed, flat, protruded, can be known. The deformation degree data may include at least one specific electrical conductor layer 151, the distance between the straight edge 131 and the position of the touch surface 210, and the deformation degree. In addition, the deformation degree signal may be, for example, a change value of the touch capacitance.

In the embodiment, the electrical conductor layers 151 of the deformation degree measuring member 140 may be sequentially arranged from the first edge 143 of the measuring surface 142 toward the second edge 144 in an increasing manner of the electrical impedance values or a decreasing manner of the electrical impedance values. Accordingly, different deformation degree signals (the variation in the touch capacitance) may be generated while the straight edge 131 of the conductive reference member 130 contacts the electrical conductor layers 151 having different electrical impedance values, which facilitates the computer 110 to generate the deformation degree data corresponding to the position of the touch surface 210 after receiving the deformation degree signal. In addition, in the embodiment, each deformation degree measuring member 140 may further include two electrical insulation layers 153 disposed on the measuring surface 142. One of the electrical insulation layers 153 is disposed between the electrical conductor layers 151 and the first edge 143, and another one of the electrical insulation layers 153 is disposed between the electrical conductor layers 151 and the second edge 144, that is, the electrical conductor layers 151 are disposed between the two electrical insulation layers 153. While detecting the deformation degree of the touch surface 210 of the capacitive touch device 200, if the deformation degree measuring member 140 is inserted in the space 160, the bottom surface 146 is brought into contact with a position of the touch surface 210, and the straight edge 131 contacts at least one of the electrical insulation layers 153 of the deformation degree measuring member 140, an overly large deformation degree (greatly-recessed or greatly-protruded) in the touch surface 210 is indicated and the capacitive touch device 200 is regarded as a defective product. That is, when the electrical insulation layers 153 of the deformation degree measuring member 140 contacts the straight edge 131, the capacitive touch device 200 does not sense the variation in the touch capacitance or a weak variation in the touch capacitance, and the computer 110 may not receive any deformation degree signal generated by the capacitive touch device 200 or may receive a weak deformation degree signal. By the program design, the computer 110 may generate the deformation degree data having the content including greatly-recessed, greatly-protruded, obsolete, or unqualified in the detecting where the capacitive touch device 200 receiving no deformation degree signal or receiving a weak deformation degree signal. Regarding the weak deformation degree signal, for example, a threshold value can be set as a judgment standard, and the threshold value can be set in accordance with the practical condition. In addition, the conductive base 141 may further include an electrically conductive adhesion layer 155, the electrical conductor layers 151 and the electrical insulation layers 153 may adhere to the measuring surface 142 of the conductive base 141 by the electrically conductive adhesion layer 155.

The angle α of the conductive base 141 of the deformation degree measuring member 140 may be 2° to 70° , such as 15° , 30° , 45° , or 60° , etc., but the invention is not limit thereto. In addition, the straight edge 131 of the conductive reference member 130 has a height H with respect to the touch surface 210. The height H may be 0.5 mm to 1000 mm, such as 1 mm, 50 mm, 100 mm, or 500 mm, etc., and the height H may be set according to the size of the capacitive touch device 200, but the invention is not limited thereto.

In the deformation degree measuring member 140, a first connecting line 152 is formed between two adjacent ones of the electrical conductor layers 152, and the measuring surface 142 of the conductive base 141 further has a side edge 145. The side edge 145 is connected between the first edge 143 and the second edge 144. Besides, the conductive base 141 further has a side surface 147 and deformation degree marks 148. The side surface 147 connects the side edge 145 of the measuring surface 142 and the bottom surface 146. The deformation degree marks 148 are disposed on the side surface 147, and the deformation degree marks 148 are corresponding in position with the first connecting lines 152. In addition, in the deformation degree measuring member 140, a second connecting line 154 may be formed between adjacent electrical conductor layer 151 and electrical insulation layers 153. The deformation degree marks 148 are corresponding in positions with the first connecting lines 152 and the second connecting lines 154. Accordingly, when the deformation degree measuring member 140 is inserted in the space 160, the bottom surface 146 of the conductive base 141 contacts a position of the touch surface 210, and the straight edge 131 of the conductive reference member 130 contacts at least one of the electrical conductor layers 151 and/or one of the electrical insulation layers 153 of the deformation degree measuring member 140, the position relationship between the straight edge 131 of the conductive reference member 130, the first connecting lines 152, and the second connecting lines 154 can be visually compared, and then finding out which one of the electrical conductor layers 151 and/or which one of the electrical insulation layers 153 contact the straight edge 131 of the conductive reference member 130, and thereby determining the deformation degree of the position of the touch surface 210 and recoding it manually.

The deformation degree marks 148 may be, for example, color blocks adhered to the side surface 147 of the conductive base 141, recessed portions formed on the side surface 147, or the like, the manner of disposing the deformation degree marks 148 is not limited in the embodiment.

The number of the deformation detecting component 170 may be one or more, the number of the deformation degree measuring member 140 of each deformation detecting component 170 may be one or more, and the number of the electrical conductor layer 151 may be one or more. In the embodiment, the number of the deformation detecting component 170 is exemplified as one, the number of the deformation degree measuring member 140 of each deformation detecting component 170 is exemplified as one, and the number of the electrical conductor layer 151 of each deformation degree measuring member 140 is exemplified as two, but it is not limited thereto.

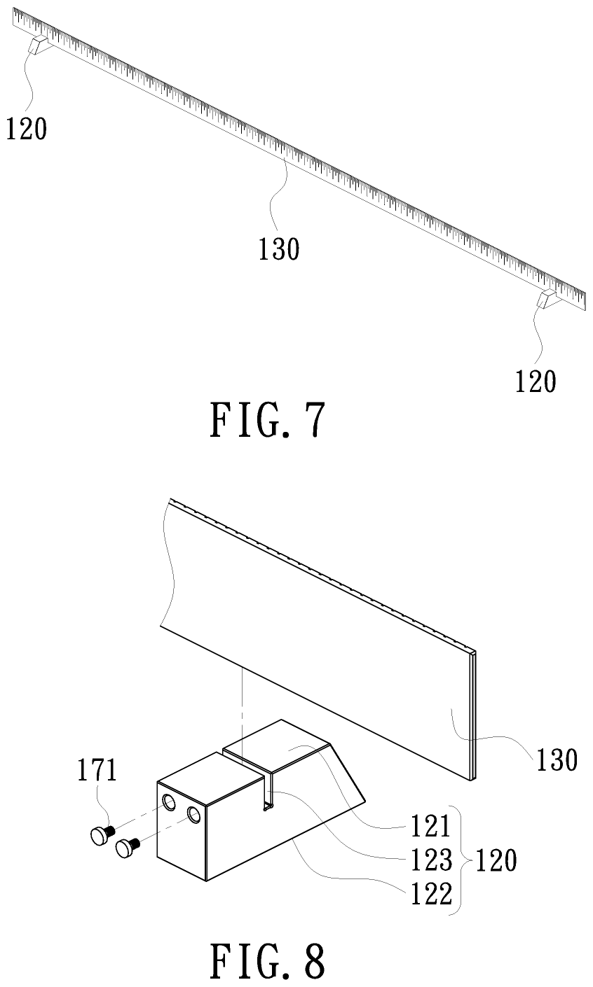

FIG. 7 is a schematic component view of conductive supporters and a conductive reference member shown in FIG. 1. FIG. 8 is a schematic exploded view of the conductive supporters and the conductive reference member shown in FIG. 7. Referring to FIGS. 2, 3, 7, and 8, in the embodiment, the deformation detecting component 170 further includes fixing members 171. The conductive reference member 130 is fixed on the conductive supporters 120 by the fixing members 171. In the embodiment, each of the conductive supporters 120 may further include a top end 121 and a bottom end 122 opposite the top end 121, and a slot 123. The slot 123 is disposed on the top end 121 and is concaved from the top end 121 toward the bottom end 122. The two ends of the conductive reference member 130 are longitudinally inserted into the slots 123 of the two conductive supporters 120 respectively. The fixing members 171 are transversely mounted on the conductive supporters 120 and abut against the two ends of the conductive reference member 130 that has been inserted into the slots 123, so as to fix the conductive reference member 130 on the conductive supporters 120. The fixing members 171 may be, for example, screws, but it is not limited thereto. By releasing the fixing members 171, the distance between the two conductive supporters 120 is adjusted to dispose the conductive supporters 120 on the frame 220 of the capacitive touch device 200.

When the detecting method 100 of the embodiment detects the deformation degree of the touch surface 210 of the capacitive touch device 200, the inspector only needs to mount the conductive reference member 130 having the straight edge 131 on the conductive supporters 120 to form the space 160 between the straight edge 131 of the conductive reference member 130, the conductive supporters 120, and the touch surface 210. And then inserting the deformation degree measuring member 140 in the space 160 to make the bottom surface 146 of the conductive base 141 of the deformation degree measuring member 140 contact a position of the touch surface 210. When at least one of the electrical conductor layers 151 which are sequentially arranged on the measuring surface 142 of the conductive base 141 from the first edge 143 toward the second edge 144 contacts the straight edge 131 of the conductive reference member 130, the capacitive touch device 200 generates the deformation degree signal correspondingly. Lastly, the computer 110 can receive the deformation degree signal generated by the capacitive touch device 200 and generate the deformation degree data corresponding to the position of the touch surface 210 according to the deformation degree signal, the inspector can know the deformation degree of the touch surface 210 of the capacitive touch device 200 according to the deformation degree data. It can be seen that the operation procedure of the detecting system 100 of the embodiment is simple and convenient, and the training time for training the inspector and the detection time for detecting the deformation degree of the touch surface 210 of the capacitive touch device 200 can be reduced, and thereby reducing the time cost of detection. Meanwhile, the detecting system 100 of the embodiment has a simple structure, and is easy to disassemble and assemble, hence, the detecting system 100 of the embodiment is convenient for carrying, and is low-cost in the time and in the space for system construction. Therefore, the detecting system 100 of the embodiment is low-cost in detecting deformation degree and has good portability.

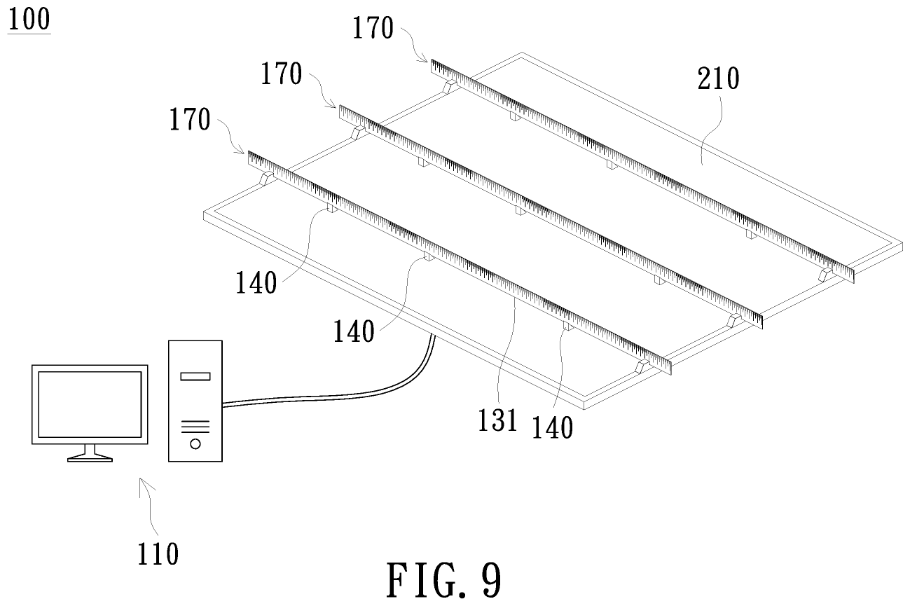

FIG. 9 is a use schematic diagram of a detecting system in accordance with an embodiment of the invention. Referring to FIG. 9, in the detecting system 100 of the embodiment, the number of the deformation detecting component 170 is plural, and the number of the deformation degree measuring member 140 of each deformation detecting component 170 is plural. The deformation degree measuring members 140 of each deformation detecting component 170 is inserted in the space (without reference numeral) formed between the straight edge 131 of the conductive reference member 130, the conductive supporters (without reference numeral), and the touch surface 210. The bottom surfaces of the conductive bases of the plurality of deformation degree measuring members 140 contact a plurality of positions of the touch surface 210 respectively. When at least one of the electrical conductor layers and/or one of the electrical insulation layers of each deformation degree measuring members 140 is/are contact the straight edge 131 of the conductive reference member 130, the capacitive touch device 200 can generate the deformation degree signals corresponding to the positions at the same time. The computer 100 can receive the deformation degree signals and generate the deformation degree data corresponding to the positions of the touch surface 210 according to the deformation degree signals. The inspector can know the deformation degrees of the touch surface 210 of the capacitive touch device 200 according to the deformation degree data. By the plurality of deformation detecting assemblies 170 and/or the plurality of deformation degree measuring members 140, the deformation degrees at the plurality of positions of the touch surface 210 can be detected at the same time, and thereby enhancing the detection efficiency.

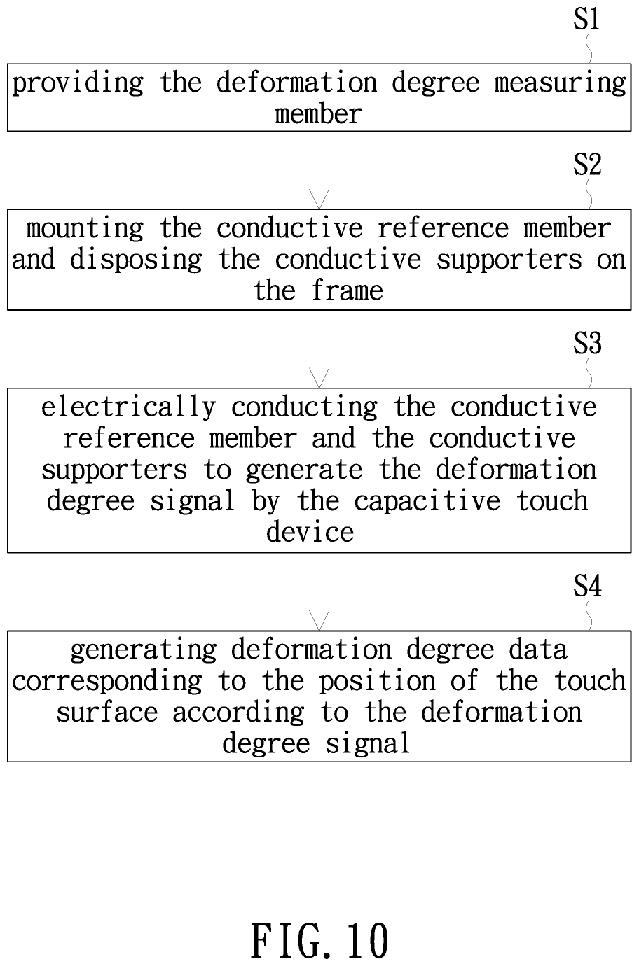

FIG. 10 is a flow diagram of a detecting method in accordance with an embodiment of the invention. Referring to FIGS. 1 to 6, and 10, the detecting method of the embodiment is for detecting the deformation degree of a touch surface 210 of a capacitive touch device 200. The capacitive touch device 200 includes the touch surface 210 and a frame 220. The frame 220 is connected to a peripheral edge of the touch surface 210. The detecting method of the embodiment includes: step S1: providing the deformation degree measuring member 140; step S2: mounting the conductive reference member 130 and disposing the conductive supporters 120 on the frame 220; step S3: electrically conducting the conductive reference member 130 and the conductive supporters 120 to generate the deformation degree signal by the capacitive touch device 200; and step S4: generating deformation degree data corresponding to the position of the touch surface 210 according to the deformation degree signal.

In step S1, the deformation degree measuring member 140 includes a conductive base 141 and a plurality of electrical conductor layers 151. The conductive base 141 has a measuring surface 142 and a bottom surface 146. The measuring surface 142 has a first edge 143 and a second edge 144 opposite to the first edge 143. The bottom surface 146 is connected to the first edge 143 of the measuring surface 142, and an acute angle a is formed between the bottom surface 146 and the measuring surface 142 of the conductive base 141. The electrical conductor layers 151 are sequentially arranged on the measuring surface 142 of the conductive base 141 from the first edge 143 toward the second edge 144, and the electrical conductor layers 151 have different electrical impedance values.

In step S2, two opposite ends of the conductive reference member 130 are mounted on two conductive supporters 120 respectively and the conductive supporters 120 are mounted on the frame 220, so as to locate the conductive reference member 130 above the touch surface 210 and form a space 160 between a straight edge 131 of the conductive reference member 130, the conductive supporters 120, and the touch surface 210.

In step S3, the deformation degree measuring member 140 is inserted into the space 160 to bring the bottom surface 146 of the conductive base 141 of the deformation degree measuring member 140 into contact with the position of the touch surface 210. When at least one of the electrical conductor layers 151 of the deformation degree measuring member 140 is brought into contact with the straight edge 131 of the conductive reference member 130, the conductive reference member 130 and the conductive supporters 120 are electrically conducted, and thereby causing the capacitive touch device 200 to generate the deformation degree signal.

In step S4, the computer 110 is electrically connected to the touch surface 210 of the capacitive touch device 200 and receives the deformation degree signal from the capacitive touch device 200, and generates the deformation degree data corresponding to the position of the touch surface 210 according to the deformation degree signal.

Although the detecting method of the embodiment is described with reference to the detecting system 100 of FIGS. 1 to 6, but it is not limited thereto. The detecting system 100 may be replaced with the detecting method 100 of any one of the above-mentioned embodiments.

Based on the above, when applying the detecting system and the detecting method of the invention to detect the deformation degree of the touch surface of the capacitive touch device, the inspector only needs to mount the conductive reference member having the straight edge on the conductive supporters to form the space between the straight edge of the conductive reference member, the conductive supporters, and the touch surface, and then inserting the deformation degree measuring member into the space to bring the bottom surface of the conductive base of the deformation degree measuring member into contact with a position of the touch surface and bring at least one of the electrical conductor layers sequentially arranged on the measuring surface of the conductive base from the first edge toward the second edge into contact with the straight edge, so as to cause the capacitive touch device to generate the deformation degree signal. Lastly, the computer is utilized to generate the deformation degree data corresponding to the position of the touch surface according to the deformation degree signal, and the inspector can know the deformation degree of the touch surface of the capacitive touch device. Accordingly, the detecting system and the detecting method of the invention can reduce the time cost for detecting the deformation degree. In addition, the detecting system of the invention and the detecting tool (the conductive reference member, the conductive supporters, the deformation degree measuring member, and the computer) used in the detecting method of the invention have a simple structure, and are easy to disassemble and assemble, and thereby being convenient for carrying.

The foregoing description of the preferred embodiment of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations can be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “The invention” or the like is not necessary limited the claim scope to a specific embodiment, and the reference to particularly preferred exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which can allow a searcher to quickly ascertain the subject matter of the technical disclosure of any patent issued from this disclosure. It is submitted with the understanding that it cannot be used to interpret or limit the scope or meaning of the claims. Any advantages and benefits described may not apply to all embodiments of the invention. It should be appreciated that variations may be made in the embodiments described by persons skilled in the art without departing from the scope of the invention as defined by the following claims. Moreover, no element and component in the disclosure is intended to be dedicated to the public regardless of whether the element or component is explicitly recited in the following claims. Furthermore, the terms such as the first edge and the second edge, are only used for distinguishing various elements and do not limit the number of the elements.

What is claimed is:

1. A detecting system, configured to detect a deformation degree of a touch surface of a capacitive touch device, and comprising at least one deformation detecting component and a computer, wherein:
the at least one deformation detecting component comprises two conductive supporters, a conductive reference member, and the at least one deformation degree measuring member, the two conductive supporters are opposite to each other, two opposite ends of the conductive reference member are mounted on the two conductive supporters respectively, and the conductive reference member has a straight edge, a space is formed between the straight edge, the two conductive supporters and the touch surface, and
the at least one deformation degree measuring member comprises a conductive base and a plurality of electrical conductor layers, the conductive base has a measuring surface and a bottom surface, the measuring surface has a first edge and a second edge opposite to the first edge, the bottom surface is connected to the first edge, and an acute angle is formed between the bottom surface and the measuring surface, the plurality of electrical conductor layers are sequentially arranged on the measuring surface from the first edge toward the second edge, and the plurality of electrical conductor layers have different electrical impedance values,
wherein when the at least one deformation degree measuring member is inserted into the space and the bottom surface contacts a position of the touch surface, at least one of the plurality of the electrical conductor layers of the at least one deformation degree measuring member contacts the straight edge, the capacitive touch device correspondingly generates a deformation degree signal; and
the computer receives the deformation degree signal and generates a deformation degree data corresponding to the position of the touch surface according to the deformation degree signal.

2. The detecting system according to claim 1, wherein in the at least one deformation detecting components, the acute angle of the conductive base of the at least one deformation degree measuring member is 2° to 70°.

3. The detecting system according to claim 1, wherein in the at least one deformation detecting components, the straight edge of the conductive reference member has a height relative to the touch surface, and the height is 0.5 mm to 1000 mm.

4. The detecting system according to claim 1, wherein in the at least one deformation detecting components, the plurality of electrical conductor layers of the at least one deformation degree measuring member are sequentially arranged from the first edge toward the second edge in a manner that the electrical impedance values of the electrical conductor layers are decreasing or increasing.

5. The detecting system according to claim 1, wherein in the at least one deformation detecting components, the at least one deformation degree measuring member further comprises two electrical insulation layers, the two electrical insulation layers are disposed on the measuring surface, and one of the two electrical insulation layers is located between the plurality of electrical conductor layers and the first edge, the other one of two electrically insulation layers is located between the plurality of electrical conductor layers and the second edge.

6. The detecting system according to claim 5, wherein in the at least one deformation detecting component, the plurality of electrical conductor layers of the at least one deformation degree measuring member are sequentially arranged from the first edge toward the second edge and between the two electrical insulation layers in a manner that the electrical impedance values of the electrical conductor layers are decreasing or increasing.

7. The detecting system according to claim 1, wherein in the at least one deformation detecting component, the at least one deformation degree measuring member further comprises at least one first connecting line, the at least one first connecting line is formed between two adjacent of the plurality of electrical conductor layers, the measuring surface further has a side edge, the side edge is connected between the first edge and the second edge, and the conductive base further has a side surface and at least one deformation degree mark, the side surface of the conductive base is connected to the side edge of the measuring surface and the bottom surface, the at least one deformation degree mark is disposed on the side surface, and a position of the at least one deformation degree mark corresponds to the at least one first connecting line.

8. The detecting system according to claim 1, wherein the at least one deformation detecting component further comprises two fixing members, and in the at least one deformation detecting component, the conductive reference member is fixed on the two conductive supporters by the two fixing members.

9. The detecting system according to claim 1, wherein the capacitive touch device comprises a frame, the frame is connected to a peripheral edge of the touch surface, when the two conductive supporters of the at least one deformation detecting component are oppositely disposed on the frame, the conductive reference member of the at least one deformation detecting component is located above the touch surface, and the computer is electrically connected to the touch surface to receive the deformation degree signal.

10. A detecting method for detecting the deformation degree of a touch surface of a capacitive touch device, wherein the capacitive touch device comprises the touch surface and a frame, the frame is connected to a peripheral edge of the touch surface, and the detecting method comprises:
providing at least one deformation degree measuring member, wherein the at least one deformation degree measuring member comprises a conductive base and a plurality of electrical conductor layers, the conductive base has a measuring surface and a bottom surface, the measuring surface has a first edge and a second edge opposite to the first edge, the bottom surface is connected to the first edge, and an acute angle is formed between the bottom surface and the measuring surface, the plurality of electrical conductor layers are sequentially arranged on the measuring surface from the first edge toward the second edge, and the electrical conductor layers have different electrical impedance values;
mounting two opposite ends of a conductive reference member on two conductive supporters and disposing the two conductive supporters on the frame, so as to locate the conductive reference member above the touch surface and form a space between a straight edge of the conductive reference member, the two conductive supporters, and the touch surface;
inserting the at least one deformation degree measuring member into the space to make the bottom surface of the conductive base of the at least one deformation degree measuring member contact a position of the touch surface, when at least one of the plurality of electrical conductor layers of the at least one deformation degree measuring member contacts the straight edge, electrically conducting the conductive reference member and the two conductive supporters to make the capacitive touch device generate a deformation degree signal; and
receiving the deformation degree signal by a computer electrically connected to the touch surface and generating a deformation degree data corresponding to the position of the touch surface according to the deformation degree signal.
